(19) United States
(12) Patent Application Publication
(10) Pub. No.: US 2007/0049068 A1
(43) Pub. Date: Mar. 1, 2007

(54) Electronic apparatus

(75) Inventor: Atsuhiro Yanagida, Tokyo (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Kabushiki Kaisha Toshiba

(21) Appl. No.: 11/510,302

(22) Filed: Aug. 25, 2006

(30) Foreign Application Priority Data
Aug. 26, 2005 (JP) P2005-246262

(51) Int. Cl. H05K 1/00

(52) U.S. Cl. 439/76.1

(57) ABSTRACT

According to an embodiment of the invention, an electronic apparatus comprises a casing, a circuit board contained in the casing, and a shock absorbing member interposed between the casing and the circuit board.

### CROSS-REFERENCE TO RELATED APPLICATIONS

This application is based upon and claims the benefit of priority from Japanese Patent Application No. P2005-246262, filed Aug. 26, 2005, the entire contents of which are incorporated herein by reference.

### BACKGROUND

1. Field

The present invention relates to an electronic apparatus having a circuit board contained in a casing, and more particularly, to a structure of the electronic apparatus for protecting the circuit board from an impact applied to the casing

2. Description of the Related Art

The electronic apparatus such as a portable computer, a mobile phone, has a circuit board contained in a casing. Electronic parts such as a CPU, a connector are mounted on this circuit board. On the other hand, a lower wall of the casing has a plurality of projections in a columnar shape which are protruded into the casing. The circuit board is fixed to the casing by being secured with screws to tip ends of these projections.

Besides the above, a method of fixing the circuit board to the casing by, for example, bonding agent has been proposed (Refer to JP-A-2004-47894, for example). The wiring board disclosed in JP-A-2004-47894 is temporarily fixed to the casing by thermosetting bonding substance. Then, the thermosetting substance is heated and cured to allow the fixing to be durable.

When the electronic apparatus has been dropped, by mistake, from a hand or a table, the casing of the electronic apparatus will receive an impact of collision against the ground or a floor. In case where the circuit board is fixed to the casing by screwing or bonding, for example, there is such anxiety that the impact which the casing has received may be directly transferred to the circuit board contained in the casing, and the circuit board may be damaged.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the invention;

FIG. 2 is an exemplary sectional view taken along a line A-A of a main body as shown in FIG. 1;

FIG. 3 is an exemplary exploded sectional view of the main body as shown in FIG. 2;

FIG. 4 is an exemplary perspective view of a mobile phone according to a second embodiment of the invention;

FIG. 5 is an exemplary sectional view of a main body as shown in FIG. 4;

FIG. 6 is an exemplary perspective view of a mobile phone according to a third embodiment of the invention; and

FIG. 7 is an exemplary sectional view of a main body as shown in FIG. 6.

### DETAILED DESCRIPTION

Various embodiments according to the invention will be described hereinafter with reference to the accompanying drawings. In general, according to one embodiment of the invention, an electronic apparatus includes: a casing; a circuit board contained in the casing; and a shock absorbing member interposed between the casing and the circuit board.

Embodiments of the invention will be described referring to the drawings in which the invention is applied to a portable computer

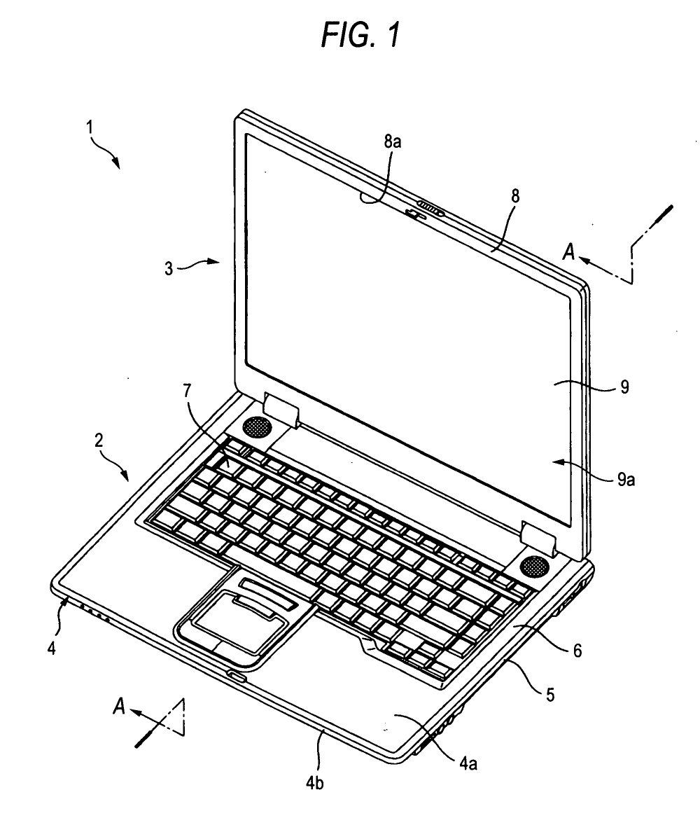

In FIGS. 1 to 3, there is disclosed a portable computer 1 as an electronic apparatus according to a first embodiment of the invention. As shown in FIG. 1, the portable computer 1 includes a main body 2 and a display unit 3

The main body 2 includes a casing 4. The casing 4 has a housing base 5 and a housing cover 6. The housing cover 6 is fitted to the housing base 5 from the above. Accordingly, the casing 4 is formed in a shape of a box having an upper wall 4a, side walls 4b and a lower wall 4c. The casing 4 is formed of thermosetting resin, for example. The upper wall 4a of the casing 4 supports a keyboard 7

As shown in FIG. 1, the display unit 3 includes a display housing 8, and a liquid crystal display panel 9 contained in this display housing 8. The liquid crystal display panel 9 has a display screen 9a. The display screen 9a is exposed to an outside of the display housing 8, through an opening 8a in a front face of the display housing 8.

The display unit 3 is held on a back end part of the casing 4 by a hinge unit which is not shown. Accordingly, the display unit 3 can be rotated between a closed position in which it is fallen so as to cover the upper wall 4a from the above and an open position in which it is erected so that the upper wall 4a and the display screen 9a may be exposed.

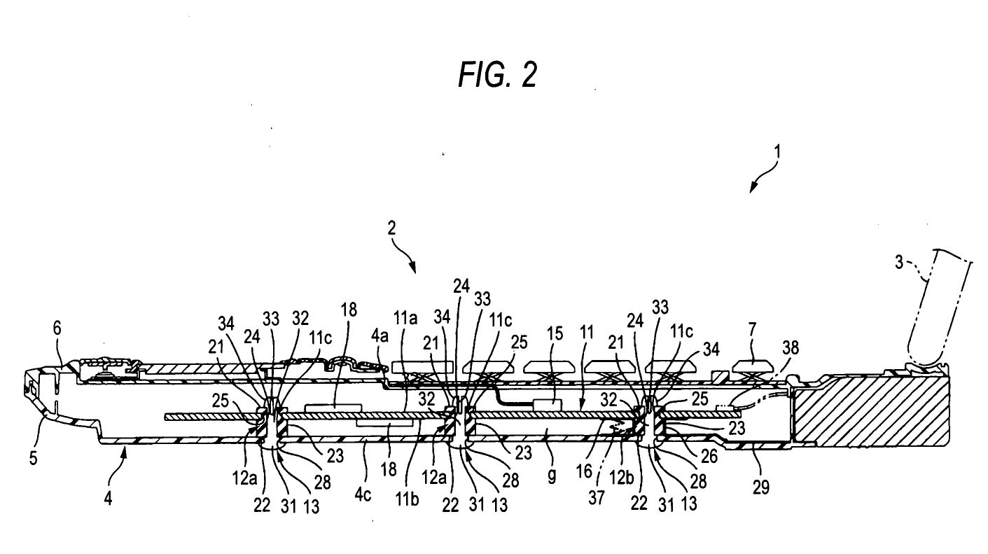

As shown in FIG. 2, the casing 4 of the main body 2 contains a circuit board 11, bushings 12a, 12b, and rivets 13. The circuit board 11 is a so-called rigid board having no flexibility. Electronic parts 18 such as a CPU (not shown), a connector 15 are mounted on the circuit board 11.

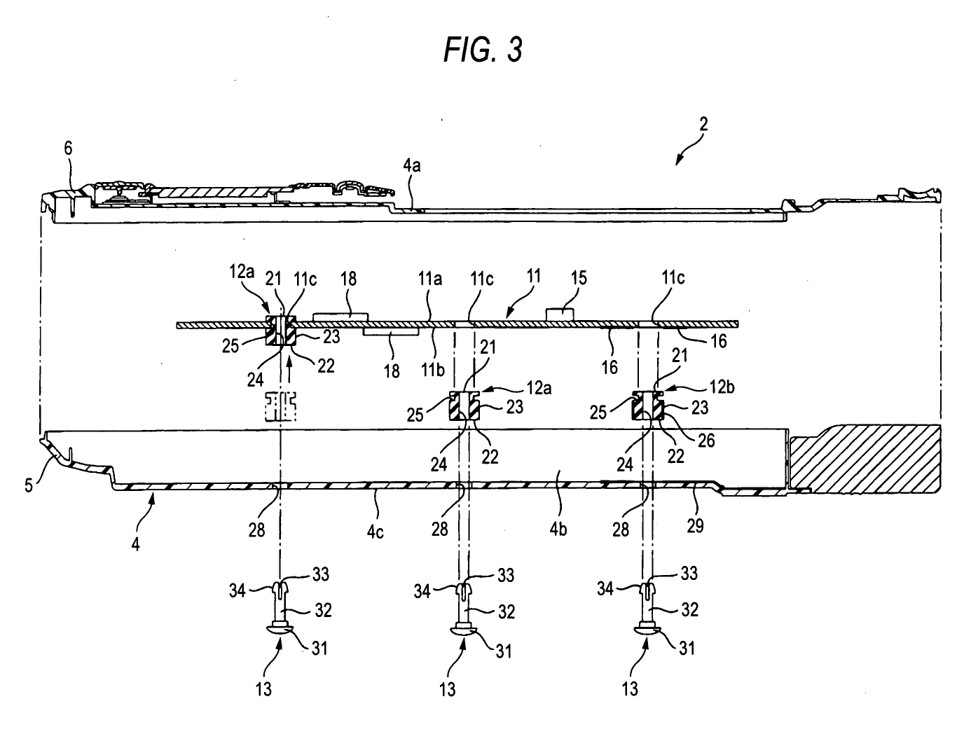

The circuit board 11 has an upper face 11a which is opposed to the upper wall 4a of the casing 4, and a lower face 11b which is opposed to the lower wall 4c of the casing 4. As shown in FIG. 3, the circuit board 11 is further provided with a plurality of fitting holes 11c passing it through from the upper face 11a to the lower face 11b. As shown in FIG. 3, the lower face 11b of the circuit board 11 has a first conductive layer 16 for earthing the circuit board 11.

The bushings 12a, 12b are an example of shock absorbing members. As shown in FIG. 3, the bushings 12a, 12b are so arranged as to correspond to the fitting holes 11c of the circuit board 11. Each of the bushings 12a, 12b is formed in a cylindrical shape, and has an upper face 21, a lower face 22, and a side face 23 in a curved shape. Each of the bushings 12a, 12b has an outer diameter which is slightly larger than that of the fitting hole 11c of the circuit board 11. Each of the bushings 12a, 12b has a through hole 24 and a fitting groove 25. The through hole 24 passes through a center of the bushing 12a, 12b from the upper face 21 to the lower face 22. The fitting groove 25 is formed along an outer circumference of the side face 23.

As illustrated by the bushing 12a on the left hand in FIG. 3, the bushings 12a, 12b are fitted to the circuit board 11 by respectively engaging the fitting grooves 25 with the fitting holes 11c of the circuit board 11. As shown in FIG. 2, the bushings 12a, 12b are interposed between the circuit board 11 and the rivets 13. The bushings 12a, 12b are arranged between the lower face 11b of the circuit board 11 and the lower wall 4c of the casing 4 thereby to form a gap g between the lower face 11b of the circuit board 11 and the lower wall 4c of the casing 4.

As shown in FIG. 3, the busing 12b has a second conductive layer 26 on its surface. As shown in FIG. 2, the second conductive layer 26 will be electrically connected to the first conductive layer 16, when the bushing 12b is fitted to the circuit board 11.

As material for the bushings 12a, 12b, resin having elasticity such as rubber, urethane, for example, is preferably employed. However, material of any type and any shape can be employed, provided that the material has elasticity or plasticity and can absorb an impact.

As shown in FIG. 3, the lower wall 4c of the casing 4 has insertion holes 28 at respective positions corresponding to the through holes 24 of the bushings 12a, 12b. The insertion holes 28 are open to the exterior of the casing 4. The lower wall 4c has a third conductive layer 29 at a position where the bushing 12b is to be fitted. The third conductive layer 29 is electrically connected to a ground (not shown) which is provided in the casing 4. When the circuit board 11 is received in the casing 4, the second conductive layer 26 is electrically connected to the third conductive layer 29, as shown in FIG. 2.

The rivet 13 is an example of fixing members. As shown in FIG. 3, the rivet 13 has a head portion 31, a shaft portion 32, a forked end portion 33, and a hook portion 34. The shaft portion 32 is projected and extended from the head portion 31. The forked end portion 33 is provided at a projected end of the shaft portion 32 so as to cut the shaft portion 32 along its projecting direction. Accordingly, the shaft portion 32 is allowed to flex in a direction perpendicular to the projecting direction.

The hook portion 34 is provided at the projected end of the shaft portion 32, and has hooks protruded outwardly. As shown in FIG. 2, the rivet 13 will fix the casing 4 and the circuit board 11, by clamping the lower wall 4c of the casing 4 and the bushings 12a, 12b between the head portion 31 and the hook portion 34.

In order to assemble the main body 2 of the portable computer 1, the bushings 12a, 12b are fitted to the circuit board 11, as a first step, as shown in FIG. 3. Specifically, the bushings 12a, 12b are elastically deformed and inserted into the fitting holes 11c of the circuit board 11, and then, the fitting grooves 25 of the bushings 12a, 12b are respectively engaged with the fitting holes 11c of the circuit board 11. In this manner, the bushings 12a, 12b will be fitted to the circuit board 11. The second conductive layer 26 of the bushing 12b will be electrically connected to the first conductive layer 16 of the circuit board 11

After the bushings 12a, 12b have been fitted to the circuit board 11, the circuit board 11 is mounted on the lower wall 4c of the casing 4. The circuit board 11 is arranged in such a manner that the through holes 24 of the bushings 12a, 12b may correspond to the insertion holes 28 in the lower wall 4c of the casing 4. On this occasion, as shown in FIG. 2, the bushings 12a, 12b are interposed between the circuit board 11 and the lower wall 4c of the casing 4, and the gap g is formed between the lower face 11b of the circuit board 11 and the lower wall 4c of the casing 4.

After the circuit board 11 has been mounted on the lower wall 4c of the casing 4, the shaft portions 32 of the rivets 13 are respectively inserted into the insertion holes 28 from the below of the lower wall 4c of the casing 4, that is, from the outside of the casing 4. Directly above the insertion holes 28, the through holes 24 of the bushings 12a, 12b are open to an inside of the casing 4. The shaft portions 32 of the rivets 13 will be inserted into the through holes 24 of the bushings 12a, 12b through the insertion holes 28.

On this occasion, the forked end portions 33 of the rivets 13 have been elastically deformed in a direction to be closed. After the hook portions 34 of the rivets 13 have passed through the through holes 24 of the bushings 12a, 12b, the forked end portions 33 will be restored to their original shape, and the hook portions 34 will be laterally enlarged thereby to be respectively engaged with the upper faces 21 of the bushings 12a, 12b. In this manner, the circuit board 11 and the bushings 12a, 12b will be fixed to the lower wall 4c of the casing 4.

When the circuit board 11 is fixed to the lower wall 4c of the casing 4, the second conductive layer 26 of the busing 12b will be electrically connected to the third conductive layer 29 of the casing 4. Accordingly, the circuit board 11 will be earthed to the casing 4.

After the circuit board 11 has been fitted to the lower wall 4c of the casing 4, the housing cover 6 is fitted to the housing base 5 from the above. In this manner, the casing 4 will be completely assembled.

According to the portable computer 1 having the above described structure, impact resistance against an impact applied to the casing 4 will be enhanced. Specifically, when the portable computer 1 has been dropped from a hand or a table by mistake, a large impact of collision against the ground or a floor will be applied to the casing 4. Although this impact will be transferred from the casing 4 to the circuit board 11, there are the bushings 12a, 12b interposed between the circuit board 11 and the casing 4. A part of the impact applied to the casing 4 will be absorbed by these bushings 12a, 12b. Accordingly, the impact to be transferred to the circuit board 11 will be reduced, and the impact resistance of the portable computer 1 can be enhanced.

Particularly, it is possible to eliminate contact between the circuit board 11 and the casing 4, by interposing the bushings 12a, 12b between the circuit board 11 and the rivets 13. Specifically, by disposing the bushings 12a, 12b in a pathway of the impact to be transferred to the circuit board 11, it is possible to absorb the impact more effectively, and to enhance the impact resistance of the portable computer 1. Because the rivets 13 can be fitted to the bushings 12a, 12b from the outside of the casing 4, assembling performance of the casing 4 is improved.

Because the gap g is formed between the circuit board 11 and the casing 4 by the presence of the bushings 12a, 12b, the electronic parts 18 mounted on the lower face 11b of the circuit board 11 can be prevented from being contacted with the casing 4. This will eliminate necessity of providing projections on the lower wall 4c of the casing 4, which have been conventionally provided for forming the gap g, and the structure of the casing 4 can be simplified.

The bushing 12b is an insulating body because it is formed of the material such as rubber, for example. However, by providing the second conductive layer 26 on the surface of the bushing 12b, it is possible to earth the circuit board 11 to the casing 4.

Moreover, instead of providing the second conductive layer 26 on the bushing 12b, a spring 37 may be interposed between the circuit board 11 and the lower wall 4c of the casing 4, as shown by a two-dot chain line in FIG. 2. Specifically, an end of the spring 37 may be electrically connected to the first conductive layer 16 of the circuit board 11, and the other end may be electrically connected to the third conductive layer 29 of the casing 4, thereby to earth the circuit board 11 to the casing 4. Alternatively, a terminal 38 exclusively for earthing may be separately provided, as shown by another two-dot chain line in FIG. 2.

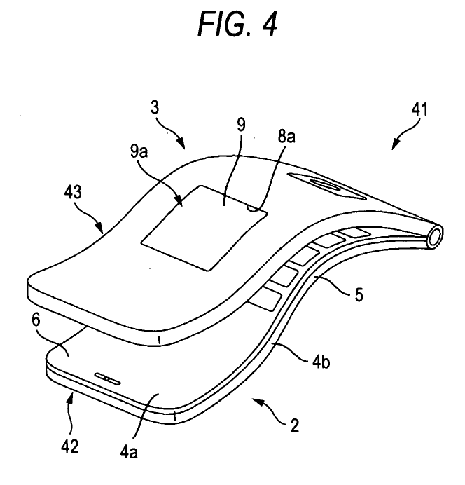

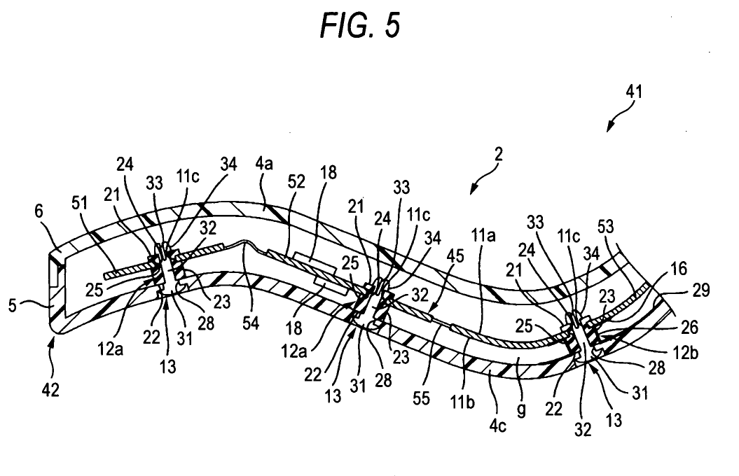

Then, another embodiment of the invention will be described referring to the drawings in which the invention is applied to a mobile phone. A mobile phone 41 as an electronic apparatus according to a second embodiment of the invention will be described referring to FIGS. 4 and 5. It is to be noted that constituents having the same functions as in the portable computer 1 according to the first embodiment will be denoted with the same reference numerals, and description of the same will be omitted.

As shown in FIG. 4, a casing 42 and a display housing 43 of the mobile phone 41 are curved in a wavelike form. The casing 42 and the display housing 43 are formed of thermosetting resin, for example.

As shown in FIG. 5, the casing 42 contains therein a circuit board 45. The circuit board 45 has a first board 51, a second board 52, a third board 53, a first flexible cable 54, and a second flexible cable 55. The first and second boards 51, 52 are so-called rigid boards having no flexibility. The third board 53 is a so-called flexible board having flexibility in itself. The first board 51 is electrically connected to the second board 52 by way of the first flexible cable 54. The second board 52 is electrically connected to the third board 53 by way of the second flexible cable 55.

Now, operation of the mobile phone 41 will be described.

The circuit board 45 is mounted on a lower wall 4c of the casing 42, in a state provided with the bushings 12a, 12b. The lower wall 4c of the casing 42 has a curved shape which is curved in a wavelike form. The circuit board 45 is mounted so as to follow the curved shape of the lower wall 4c of the casing 42. On this occasion, a curve between the first board 51 and the second board 52 is adjusted by the first flexible cable 54. A curve between the second board 52 and the third board 53 is adjusted by the curve of the third board 53 itself and the second flexible cable 55.

According to the mobile phone 41 having the above described structure, impact resistance against an impact applied to the casing 42 will be enhanced. Specifically, the mobile phone 41 has the bushings 12a, 12b. Therefore, the impact to be transferred to the circuit board 45 will be reduced, and the impact resistance of the mobile phone 41 can be enhanced, in the same manner as in the portable computer 1 according to the first embodiment.

Particularly, when the casing 42 which is curved as in this embodiment is employed, use of the bushings 12a, 12b and the rivets 13 is advantageous, as follows;

In case where it is desired to form the projections for fixing the circuit board 45 on the lower wall 4c of the casing 42, as in the prior art, it will not be easy to form the projections in the curved casing 42. In order to receive the circuit board 45 along an outer shape of the casing 42, the projections must be projected in a direction perpendicular to a wall face of the casing 42. When the casing is formed by injection molding, such projections will be inclined with respect to a direction of tightening and opening a mold. Accordingly, an extracting angle may have minus inclination in some area, and the casing will be unable to be taken out from the mold, even though the mold is opened.

On the other hand, in case where the bushings 12a, 12b and the rivets 13 are used, as in the mobile phone 41 according to the embodiment, such problem can be solved because necessity of providing the projections as described above will be eliminated. By using the bushings 12a, 12b and the rivets 13, it will be possible to fit the circuit board 45 easily along the curved face of the casing 42.

It is to be noted that all the first to third boards 51, 52, 53 of the circuit board 45 may be rigid boards, or all the boards may be flexible boards.

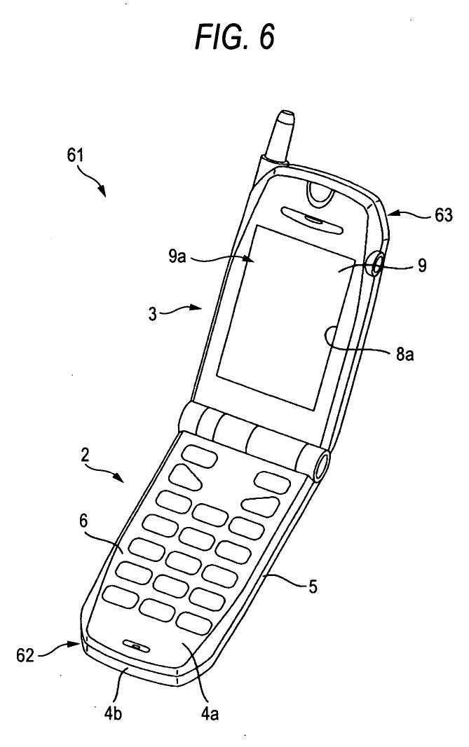

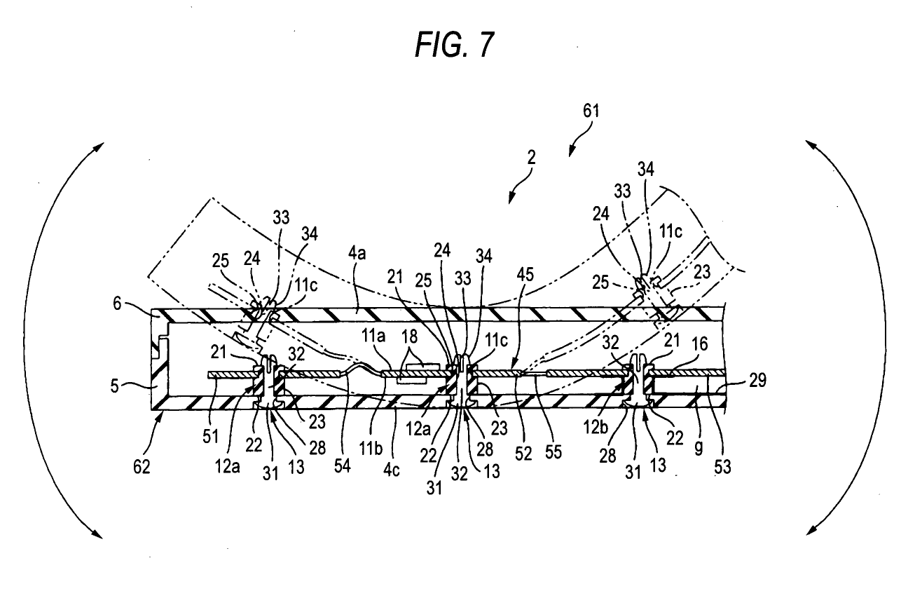

Then, a mobile phone 61 as an electronic apparatus according to a third embodiment of the invention will be described referring to FIGS. 6 and 7. It is to be noted that constituents having the same functions as in the portable computer 1 according to the first embodiment and in the mobile phone 41 according to the second embodiment will be denoted with the same reference numerals, and description of the same will be omitted.

A casing 62 and a display housing 63 of the mobile phone 61 are formed of elastic material such as rubber, for example, and has flexibility. As shown in FIG. 7, the casing 62 contains therein the circuit board 45.

According to the mobile phone 61 having the above described structure, the impact resistance against an impact applied to the casing 62 will be enhanced. Specifically, the mobile phone 61 has the bushings 12a, 12b. Therefore, the impact to be transferred to the circuit board 45 will be reduced, and the impact resistance of the mobile phone 61 can be enhanced, in the same manner as in the portable computer 1 according to the first embodiment.

Particularly, in case where the casing 62 itself is formed of the material having flexibility as in this embodiment, a part of an impact applied to the casing 62 will be absorbed by the casing 62 itself. Accordingly, the impact transferred to the circuit board 45 contained inside the casing 62 will be reduced. This contributes to the impact resistance of the mobile phone 61.

In the casing 62 having flexibility as in this embodiment, it is advantageous to use the bushings 12a, 12b. Specifically, when the casing 62 is folded or extended in a longitudinal direction or in a lateral direction, not a small stress will be exerted also on the circuit board 45 which is fixed to the casing 62. However, because the bushings 12a, 12b are interposed between the casing 62 and the circuit board 45, the stress exerted on the circuit board 45 can be reduced.

It is to be noted that the material for the casing 62 and the display housing 63 is not limited to rubber, but any kind of material can be employed, provided that the material has flexibility.

Although the portable computer 1 according to the first embodiment and the mobile phones 41, 61 according to the second and third embodiments have been described above, the invention is not limited to these embodiments. For example, the bushings 12a, 12b may be interposed between the casing 4, 42, 62 and the rivets 13. Further, in case where the casing 4, 62 is provided with the projections for fitting the circuit board 11, 45 as in the prior art, it is possible to provide the bushings 12a, 12b between the projections and the circuit board 11, 45. The shock absorbing members are interposed in any position between the casing 4, 42, 62 and the circuit board 11, 45. The position and the structure of fitting the shock absorbing members to the casing 4, 42, 62 and the circuit board 11, 45 are not important.

The fixing member is not limited to the rivet 13, but any kind of fixing member can be used, provided that the fixing member has a structure for fixing the circuit board 11, 45 to the casing 4, 42, 62. For example, the bushings 12a, 12b which have been fitted to the circuit board 11, 45 may be directly fixed to the casing 4, 42, 62 by bonding agent or the like, without using the fixing member such as the rivet 13.

In the mobile phones 41, 61 according to the second and third embodiments too, the circuit board 45 may be earthed to the casing 4 by the spring 37 or the earthing terminal 38, in the same manner as in the portable computer 1 according to the first embodiment.

The invention can be applied not only to the portable computer and the mobile phone, but also to all the electronic apparatuses having the circuit board inside the casing.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is

1. An electronic apparatus comprising:
a casing;
a circuit board contained in the casing; and
a shock absorbing member interposed between the casing and the circuit board.

2. The electronic apparatus according to claim 1, wherein the casing includes a curved surface at least a part thereof.

3. An electronic apparatus comprising:
a casing having flexibility; and
a circuit board contained in the case.

4. The electronic apparatus according to claim 3, wherein the shock absorbing member is interposed between the casing and the circuit board.

5. The electronic apparatus according to claim 1, further comprising:
a fixing member for fixing the circuit board to the casing;
wherein the shock absorbing member is interposed between the circuit board and the fixing member.

6. The electronic apparatus according to claim 4, further comprising:
a fixing member for fixing the circuit board to the casing;
wherein the shock absorbing member is interposed between the circuit board and the fixing member.

7. The electronic apparatus according to claim 5, wherein the casing has a hole which opens to an outside of the casing at a position corresponding to the shock absorbing member; and
the fixing member is engaged with the shock absorbing member through the hole from the outside of the casing.

8. The electronic apparatus according to claim 6, wherein the casing has a hole which opens to an outside of the casing at a position corresponding to the shock absorbing member; and
the fixing member is engaged with the shock absorbing member through the hole from the outside of the casing.

9. The electronic apparatus according to claim 1, wherein the circuit board has a face opposed to the casing; and
the shock absorbing member is disposed between the face of the circuit board and the casing to form a gap.

10. The electronic apparatus according to claim 4, wherein the circuit board has a face opposed to the casing; and
the shock absorbing member is disposed between the face of the circuit board and the casing to form a gap.

11. The electronic apparatus according to claim 1, wherein the shock absorbing member has a conductive layer for grounding the circuit board to the casing.

12. The electronic apparatus according to claim 4, wherein the shock absorbing member has a conductive layer for grounding the circuit board to the casing.
